(19) United States
(12) Patent Application Publication
(10) Pub. No.: US 2006/0166491 A1
(43) Pub. Date: Jul. 27, 2006

(54) Dual damascene interconnection having low k layer and cap layer formed in a common PECVD process

(76) Inventor: Kensaku Ida, Wappingers Falls, NY (US)

Correspondence Address: MAYER & WILLIAMS PC, 251 NORTH AVENUE WEST, 2ND FLOOR, WESTFIELD, NJ, 07090, US

(21) Appl. No.: 11/040,780

(22) Filed: Jan. 21, 2005

(51) Int. Cl. H01L 21/4763

(52) U.S. Cl. 438/637

(57) ABSTRACT

A method of fabricating dual damascene interconnections begins by forming on a substrate a dielectric layer by a PECVD process that employs a first precursor gas. A capping layer is formed on the dielectric layer by a PECVD process that also employs the first precursor gas such that deposition of the dielectric layer and the capping layer are performed in a continuous manner without deactivation of a plasma. A via is formed in the capping layer and the dielectric layer. The dielectric layer is partially etched to form a trench, which is connected to the via and in which interconnections will be formed. The interconnections are completed by filling the trench and the via with copper.

### FIELD OF THE INVENTION

The present invention relates generally to dual damascene interconnections for integrated circuits, and more specifically to a dual damascene interconnection having a low k layer and a cap layer formed in a common PECVD process.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD.

Many of the low k materials, however, have properties that are incompatible with other materials employed to fabricate semiconductor devices or are incompatible with processes employed to fabricate the semiconductor devices. For example, adhesion to layers formed from a low dielectric constant material by adjacent layers is often poor, resulting in delamination. Additionally, layers formed from low dielectric materials are often structurally compromised by Chemical Mechanical Polishing (CMP) processes through erosion, as well as adsorption of CMP slurry chemicals. Etching processes often produce micro-trenches and rough surfaces in layers formed from materials having low dielectric constants, which is often unsuitable for subsequent photolithography processes. As a result, these materials are problematic to integrate into damascene fabrication processes. To overcome some of these problems a cap or capping layer typically formed from a material such as SiO₂ is employed to protect the low dielectric materials during the CMP processes. The cap layer also serves as a hardmask when the vias and trenches are etched.

Unfortunately the formation of the cap layer itself can damage the underlying low k material. Both the low k material and the cap layer are generally formed by a deposition process that is referred to as chemical vapor deposition or CVD. Conventional thermal CVD processes supply reactive gases to the substrate surface where heat-induced chemical reactions take place to produce a desired film. The high temperatures at which some thermal CVD processes operate can damage device structures having layers previously formed on the substrate. To overcome this problem, a method of depositing metal and dielectric films at relatively low temperatures is often employed. Such a method is referred to as plasma-enhanced CVD (PECVD) techniques, which are described, for example, in U.S. Pat. No. 5,362,526, entitled “Plasma-Enhanced CVD Process Using TEOS for Depositing Silicon Oxide”. Plasma-enhanced CVD techniques promote excitation and/or disassociation of the reactant or precursor gases by the application of radio frequency (RF) energy to a reaction zone near the substrate surface, thereby creating a plasma of highly reactive species. The high reactivity of the released species reduces the energy required for a chemical reaction to take place, and thus lowers the required temperature for such PECVD processes.

In a conventional dual damascene process different reactant or precursor gases are used to form the low k layer and the cap layer. For example, precursor gases such as TMCTS or OMCTS are sometimes used to form the low k layers while a precursor gas such as TEOS is used to form the cap layer. Since the precursor gas used to form the low k layer is different from that used to form the cap layer, the plasma must be terminated in the chamber after formation of the low k layer and the precursor gas switched before the cap layer can be formed. Not only does this reduce the efficiency of the fabrication process because of the additional time involved, it also results in damage to the low k layer when the plasma is reactivated.

Accordingly, it would be desirable to provide a dual damascene process in which it is not necessary to terminate the plasma between formation of the low k layer and the cap layer.

### SUMMARY OF THE INVENTION

In accordance with the present invention, a method of fabricating dual damascene interconnections is provided. The method begins by forming on a substrate a dielectric layer by a PECVD process that employs a first precursor gas. A capping layer is formed on the dielectric layer by a PECVD process that also employs the first precursor gas such that deposition of the dielectric layer and the capping layer are performed in a continuous manner without deactivation of a plasma. A via is formed in the capping layer and the dielectric layer. The dielectric layer is partially etched to form a trench, which is connected to the via and in which interconnections will be formed. The interconnections are completed by filling the trench and the via with copper.

In accordance with one aspect of the invention, the first precursor gas is an organosilicon material.

In accordance with another aspect of the invention, the organosilicon material is octamethylcyclotetrasiloxane, (OMCTS).

In accordance with another aspect of the invention, the organosilicon material is 1,3,5,7-tetramethylcyclotetrasiloxane (TMCTS).

In accordance with another aspect of the invention, the step of forming the capping layer further comprises the step of selectively adjusting at least one process parameter employed in the PECVD process from that used to form the dielectric layer.

In accordance with another aspect of the invention, the process parameter is selected from the group consisting of a gas flow rate and a plasma characteristic.

In accordance with another aspect of the invention, the plasma characteristic comprises a plasma gas pressure.

In accordance with another aspect of the invention, the plasma characteristic comprises an RF power level.

In accordance with another aspect of the invention, the process parameter comprises a ratio of the precursor gas to O₂ that is introduced during the PECVD process.

In accordance with another aspect of the invention, the precursor gas is octamethylcyclotetrasiloxane, (OMCTS).

In accordance with another aspect of the invention, before the formation of the dielectric layer, forming a lower interconnection on the substrate and forming an etch stop layer on the lower interconnection.

In accordance with another aspect of the invention, the step of forming the etch stop layer is performed by a PECVD process that employs the first precursor gas such that deposition of the etch stop layer and the dielectric layer is performed in a continuous manner without deactivation of the plasma.

In accordance with another aspect of the invention, a barrier layer is formed overlying the via and the trench prior to filling the trench and the via with copper;

In accordance with another aspect of the invention, the barrier layer is selected from the group consisting of tantalum, tantalum nitride, titanium, titanium silicide or zircuonium.

In accordance with another aspect of the invention, the step of forming the via includes the step of forming a photoresist pattern on the capping layer to define the via and etching the capping layer and the dielectric layer using the photoresist pattern as an etch mask.

In accordance with another aspect of the invention, the step of forming the trench includes forming a trench photoresist pattern on the capping layer to define the trench and forming the trench by etching using the trench photoresist pattern as an etch mask.

In accordance with another aspect of the invention, an integrated circuit is provided having a dual damascene interconnection constructed in accordance with the aforementioned method.

### BACKGROUND OF THE INVENTION

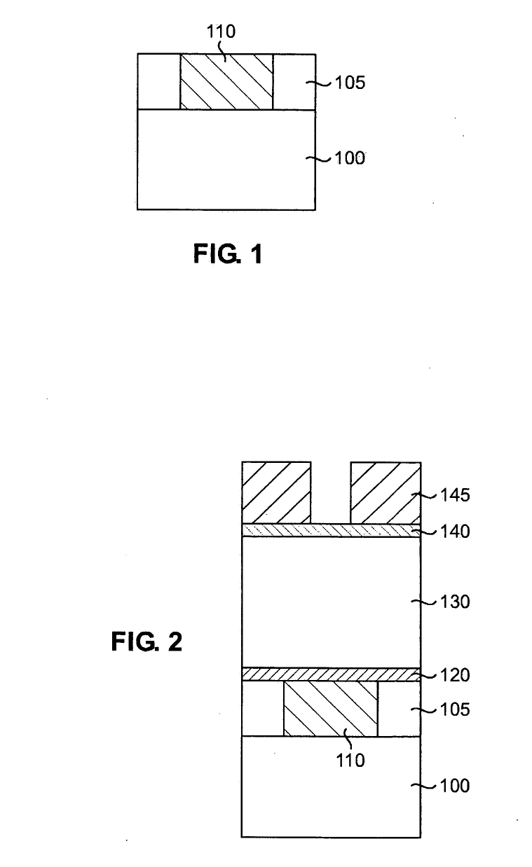

FIGS. 1-9 show cross-sectional views illustrating the formation of a dual damascene structure constructed in accordance with the present invention.

FIG. 10 shows an alternative embodiment of a dual damascene structure constructed in accordance with the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. However the present invention is also applicable to other dual damascene processes as well.

In the present invention the aforementioned problems that can arise when a cap layer and the insulating or ILD layer are formed in different deposition steps using different precursor gases is overcome by continuously depositing the ILD layer and the cap layer while the plasma remains activated during the formation of both layers. That is, the plasma employed in the PECVD process is not turned off between the formation of the ILD layer and the formation of the cap layer. As detailed below, this can be accomplished by using the same precursor gas for both the ILD layer and the cap layer, thereby eliminating the need to switch precursor gases. A method of fabricating dual damascene interconnections according to an embodiment of the present invention will now be described with reference to FIGS. 1 through 9.

As shown in FIG. 1, a substrate 100 is prepared. A lower ILD layer 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminum, and aluminum alloy. The lower interconnection 110 is preferably formed of copper because of its low resistance. Also, the surface of the lower interconnection 110 is preferably planarized.

Referring to FIG. 2, a barrier or etch stop layer 120, a low-k ILD layer 130, and a capping layer 140 are sequentially stacked on the surface of the substrate 100 where the lower interconnection 110 is formed, and a photoresist pattern 145 is formed on the capping layer 140 to define a via.

The barrier or etch stop layer 120 is formed to prevent electrical properties of the lower interconnection 110 from being damaged during a subsequent etch process for forming a via. Accordingly, the etch stop layer 120 is formed of a material having a high etch selectivity with respect to the ILD layer 130 formed thereon. In an exemplary embodiment, the etch stop layer 120 is formed of SiC, SiN, or SiCN, having a dielectric constant of 4 to 5. The etch stop layer 120 is as thin as possible in consideration of the dielectric constant of the entire ILD layer, but thick enough to properly function as an etch stop layer.

The ILD layer 130 is formed of a hybrid low-k dielectric material, which has advantages of organic and inorganic materials. That is, the ILD layer 130 is formed of a hybrid low-k dielectric material having low-k characteristics that can be formed using a conventional apparatus. The ILD layer 130 has a low dielectric constant (e.g., 3.3 or less). The ILD layer 130 may be formed of an organosilicon compound such as octamethylcyclotetrasiloxane, (OMCTS) or 1,3,5,7-tetramethylcyclotetrasiloxane (TMCTS), for example. More generally, other organosilicon compounds having ring, linear or fullerene structures may be alternatively employed.

The ILD layer 130 may be formed by introducing a processing gas that includes the organosilicon compound into a processing chamber such as a chemical vapor deposition (CVD) chamber, and more specifically, a plasma-enhanced CVD (PECVD) chamber. The ILD layer 130 is formed to a thickness of about 3,000 angstroms to 20,000 angstroms or other appropriate thicknesses determined by those skilled in the art.

In general, the deposition process parameters used to form the ILD layer 130 using a PECVD process chamber may be readily determined by those of ordinary skill in the art. Such process parameters include wafer temperature, chamber pressure, OMCTS precursor gas flow rate, oxygen enhancement gas flow rate, inert carrier gas flow rate, and RF power level. Helium (He), argon (Ar), nitrogen (N₂), or combinations thereof, among others, may be used to form the plasma.

Referring again to FIG. 2, capping layer 140 is formed over ILD layer 130. The capping layer 140 prevents the ILD layer 130 from being damaged when dual damascene interconnections are planarized using chemical mechanical polishing (CMP). The capping layer 140 also serves as a hardmask during the subsequent etching steps used to form the via and trench. The capping layer 140 may be formed of SiO₂, SiOF, SiON, SiC, SiN, or SiCN. For example, in conventional processes an organosilicon compound such as tetraethoxysilane (TEOS) is used to form an SiO₂ capping layer by PECVD. As previously mentioned, since in the conventional approach the precursor gas employed to form ILD layer 130 is different from the precursor gas employed to form the capping layer 140, the plasma must be terminated in the chamber after formation of the ILD layer 140 and the precursor gas switched before the capping layer 140 can be formed.

In accordance with the present invention, the same processing gas is used to form both the ILD layer 130 and the capping layer 140. For instance, in one embodiment of the invention, an organosilicon materials such as OMCTS is used to form both the ILD layer 130 and the capping layer 140. Of course, while the precursor gas is the same, other process parameters need to be adjusted during the transition from the formation of the ILD layer 130 to the formation of the capping layer 140. Such process parameters include the plasma conditions (e.g., RF power, pressure) and the flow rate of each of the gases, including the precursor gas, enhancement gases, and the carrier gas or gases. For instance, in some embodiments of the invention OMCTS and O₂ are introduced in a ratio of 8:1 to form ILD layer 130 and in a ratio of 1:1 to form an SiO₂ cap layer 140. In this way instead of forming a relatively sharp interface a graded interface is formed between the ILD layer 130 and the capping layer 140. The graded interface advantageously enhances adhesion between the layers. Moreover, since the plasma remains active during the deposition of both layers, damage to the ILD layer 130 is reduced, which would otherwise arise when the plasma is reactivated to deposit the capping layer 140. Of course, by eliminating the need to change the precursor gas the time needed to fabricate the dual damascene interconnections is also significantly reduced.

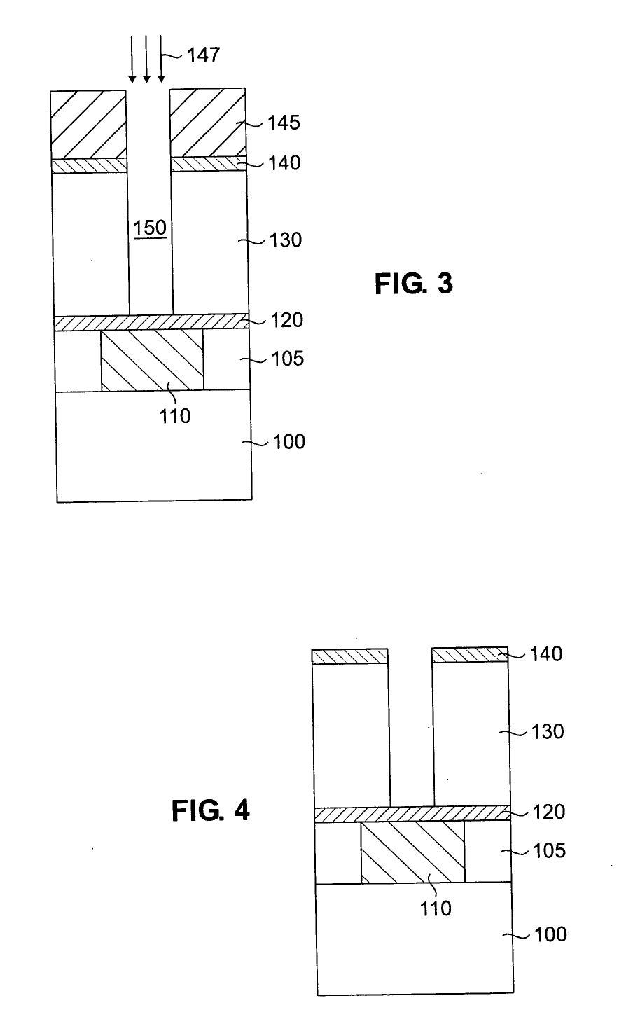

After formation of ILD layer 130 and capping layer 140, the process continues in a conventional manner by forming the via photoresist pattern 145 by depositing a layer of a photoresist and then performing exposure and developing processes using a photo mask defining a via. Referring to FIG. 3, the ILD layer 130 is anisotropically etched (147) using the photoresist pattern 145 as an etch mask to form a via 150. The ILD layer 130 can be etched, for example, using a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the ILD layer 130 is selectively etched and the etch stop layer 120 is not etched.

Referring to FIG. 4, the via photoresist pattern 145 is removed using a stripper. If the photoresist pattern 145 is removed using O₂-ashing, which is widely used for removing a photoresist pattern, the ILD layer 130, which often contains carbon, may be damaged by the O₂-based plasma. Thus, the photoresist pattern 145 alternatively may removed using an H₂-based plasma.

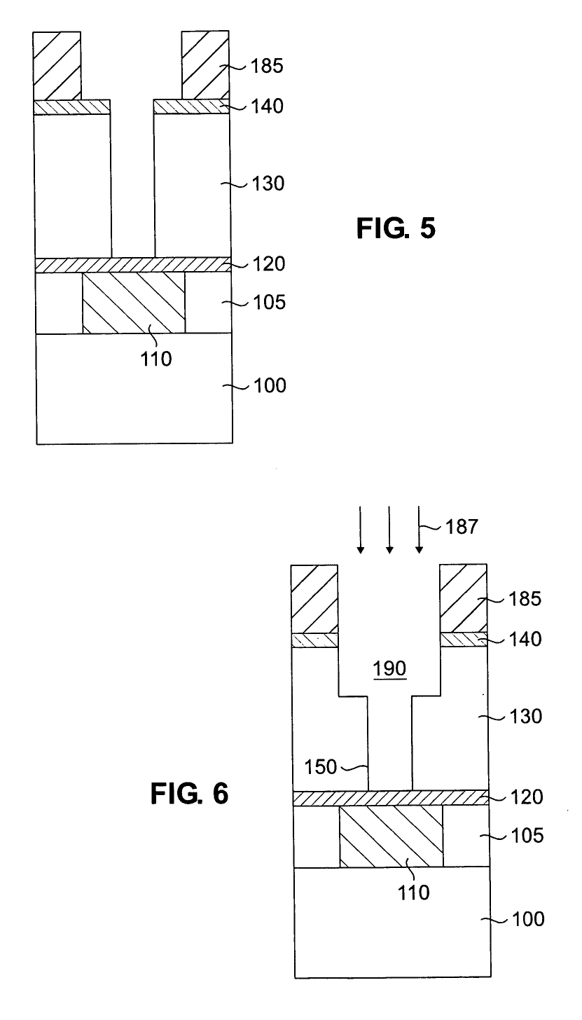

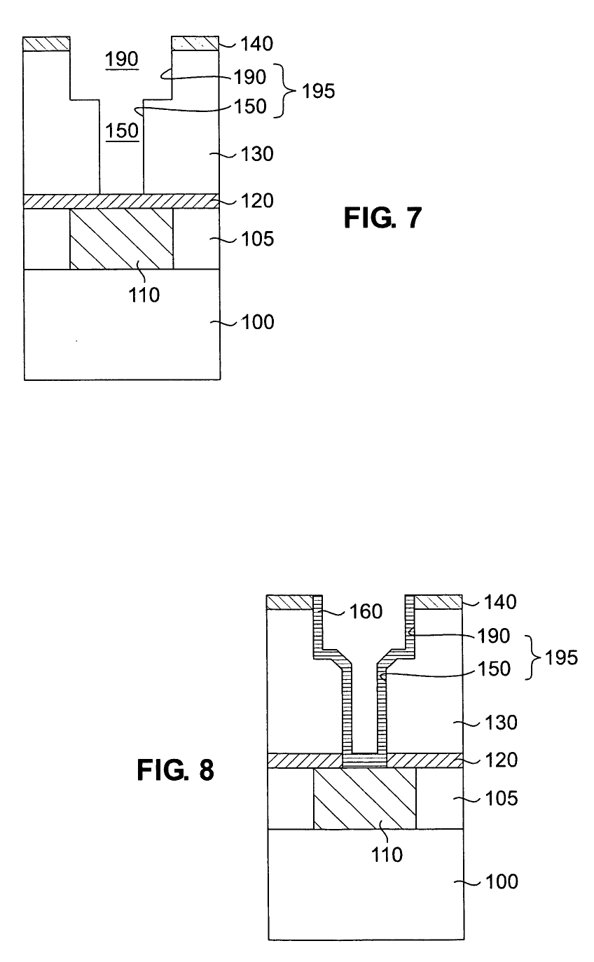

Referring to FIG. 5, a trench photoresist pattern 185 is formed, followed by formation of a trench 190 in FIG. 6. The capping layer 140 is etched using the photoresist pattern 185 as an etch mask, and then the ILD layer 130 is etched to a predetermined depth to form the trench 190. The resulting structure, shown in FIG. 7, defines a dual damascene interconnection region 195, which includes the via 150 and the trench 190.

Referring to FIG. 8, the etch stop layer 120 exposed in the via 150 is etched until the lower interconnection 110 is exposed, thereby completing the dual damascene interconnection region 195. The etch stop layer 120 is etched so that the lower interconnection 110 is not affected and only the etch stop layer 120 is selectively removed.

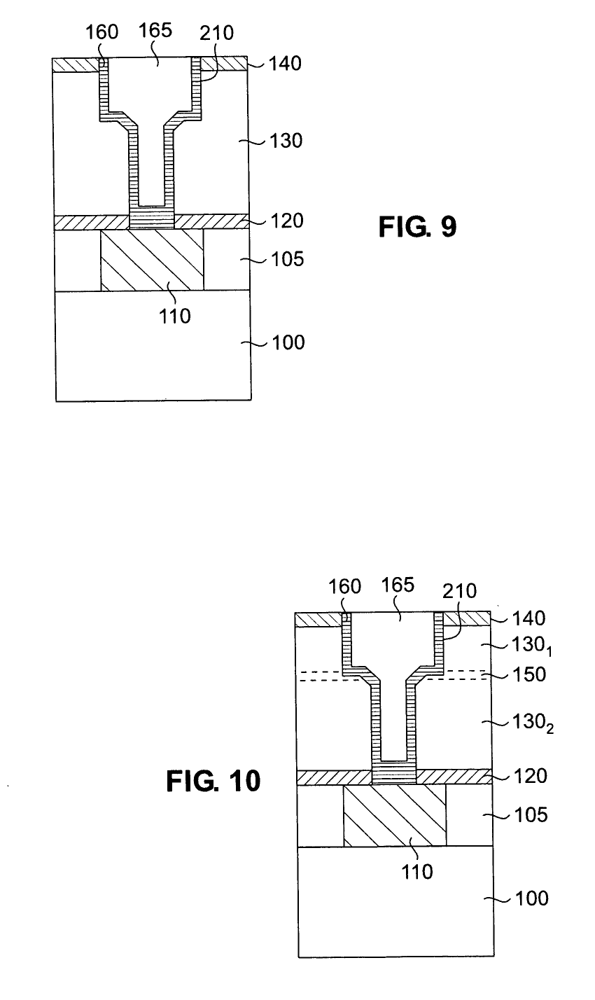

A barrier layer 160 is formed on the dual damascene interconnection region 195 to prevent the subsequently formed conductive layer from diffusing into ILD layer 130. The barrier layer 160 is generally formed from a conventional material such as tantalum, tantalum nitride, titanium, titanium silicide or zircuonium. After formation of the barrier layer 160 the copper conductive layer is formed on the barrier layer by an electroplating process. Referring to FIG. 9, the bulk copper layer 165 is formed on the dual damascene interconnection region 195 by electroplating and then planarized, thereby forming a dual damascene interconnection 210.

In one alternative embodiment of the invention, barrier or etch stop layer 120 may also be formed in a continuous manner with ILD layer 130 without the need to deactivate the plasma. That is, in this embodiment of the invention the interface between etch stop layer 120 and ILD layer 130 is a graded interface, which may be formed in a manner similar to that presented above in connection with the graded interface between ILD layer 130 and capping layer 140.

In some conventional dual damascene interconnections the low k material used for the ILD layer in which the trenches are formed is different from the low k material used for the ILD layer in which the vias are formed. For instance, in FIG. 10 the trench is formed in the upper ILD layer 130, and the via is formed in the lower ILD layer 130₂. Different materials are employed because the dielectric constant of the material in which the trench is formed is generally required to be lower than the dielectric constant of the material in which the via is formed. In the conventional process the different materials require the use of different precursor gases, which gives rise to all the attendant problems and limitations mentioned above in connection with the formation of cap layer on the ILD layer.

In accordance with some embodiments of the present invention, the upper and lower ILD layers 130, and 1302 may be formed using the same precursor gas in a continuous PECVD process, thereby reducing the damage to the lower ILD layer that could otherwise arise when the plasma is reactivated after switching precursor gases to deposit the upper ILD layer. That is, the interface 150 between the upper and lower ILD layers 130₁ and 130₂ may be a graded interface that is formed by varying the PECVD process parameters in an appropriate manner while introducing the same precursor gas during the deposition of both ILD layers.

Although various embodiments are specifically illustrated and described herein, it will be appreciated that modifications and variations of the present invention are covered by the above teachings and are within the purview of the appended claims without departing from the spirit and intended scope of the invention. For example, those of ordinary skill in the art will recognize that the via-first dual damascene process described with reference to FIGS. 1 through 10 can be applied to a trench-first dual damascene process.

1. A method of fabricating dual damascene interconnections, the method comprising:
(a) forming on a substrate a dielectric layer by a PECVD process that employs a first precursor gas;
(b) forming a capping layer on the dielectric layer by a PECVD process that employs said first precursor gas such that deposition in steps (a) and (b) are performed in a continuous manner without deactivation of a plasma;
(c) forming a via in the capping layer and the dielectric layer;
(d) partially etching the dielectric layer to form a trench, which is connected to the via and in which interconnections will be formed; and
(e) completing interconnections by filling the trench and the via with copper.

2. The method of claim 1 wherein the fist precursor gas is an organosilicon material.

3. The method of claim 1 wherein the organosilicon material is octamethylcycloterasiloxane, (OMCTS).

4. The method of claim 1 wherein the organosilicon material is 1,3,5,7-tetramethylcyclotetrasiloxane (TMCTS).

5. The method of claim 1 wherein step (b) further comprises the step of selectively adjusting at least one process parameter employed in the PECVD process from that used in step (a).

6. The method of claim 5 wherein said at least one process parameter is selected from the group consisting of a gas flow rate and a plasma characteristic.

7. The method of claim 6 wherein said plasma characteristic comprises a plasma gas pressure.

8. The method of claim 6 wherein said plasma characteristic comprises an RF power level.

9. The method of claim 5 wherein said at least one process parameter comprises a ratio of the precursor gas to O₂ that is introduced during the PECVD process.

10. The method of claim 9 wherein the precursor gas is octamethylcyclotetrasiloxane, (OMCTS).

11. The method of claim 1 further comprising, before step (a): forming a lower interconnection on the substrate; and forming an etch stop layer on the lower interconnection.

12. The method of claim 11 wherein the step of forming the etch stop layer is performed by a PECVD process that employs said first precursor gas such that deposition of the etch stop layer and the dielectric layer is performed in a continuous manner without deactivation of the plasma.

13. The method of claim 1 further comprising the step of forming a barrier layer overlying the via and the trench prior to filling the trench and the via with copper;

14. The method of claim 13 wherein the barrier layer is selected from the group consisting of tantalum, tantalum nitride, titanium, titanium silicide or zircuonium.

15. The method of claim 1, wherein step (c) comprises: forming a photoresist pattern on the capping layer to define the via; and etching the capping layer and the dielectric layer using the photoresist pattern as an etch mask.

16. The method of claim 1, wherein step (d) includes: forming a trench photoresist pattern on the capping layer to define the trench; forming the trench by etching using the trench photoresist pattern as an etch mask.

17. An integrated circuit having a dual damascene interconnection constructed in accordance with the method of claim 1.
